(19) United States
(12) Patent Application Publication
(10) Pub. No.: US 2016/0336388 A1
(43) Pub. Date: Nov. 17, 2016

(54) METHOD FOR FORMING Ti/TiN STACKED FILM AND METHOD FOR PRODUCING SEMICONDUCTOR DEVICE

(71) Applicant: Renesas Electronics Corporation, Tokyo (JP)

(72) Inventors: Takeshi HAYASHI, Hitachinaka-shi (JP); Kentaro KITA, Hitachinaka-shi (JP); Takuya KOBORI, Hitachinaka-shi (JP)

(21) Appl. No.: 15/153,205

(22) Filed: May 12, 2016

(30) Foreign Application Priority Data
May 15, 2015 (JP) 2015-099814

(51) Int. Cl. H01L 49/02; H01L 21/768

(52) U.S. Cl. CPC H01L 28/60; H01L 21/76841; H01L 21/76892; H01L 21/76834; H01L 21/76895

(57) ABSTRACT

A semiconductor device is improved in reliability and productivity. In the formation of its Ti/TiN stacked film, about a mixed gas of Ar gas and N₂ gas that is used to form a TiN film by a sputtering method, the supply of the N₂ gas is turned off (i.e., is stopped) before that of the Ar gas.

### CLAIM OF PRIORITY

The present application claims priority from Japanese Patent application serial no. 2015-099814, filed on May 15, 2015, the content of which is hereby incorporated by reference into this application.

### BACKGROUND OF THE INVENTION

1. Field of the Invention

The present invention relates to a method for producing a semiconductor device, in particular, a method for forming a Ti/TiN stacked film.

2. Description of Related Art

In a semiconductor device in which aluminum (expressed as Al hereinafter) interconnections are used, its Al film may be deteriorated in morphology (surface smoothness), so that at the time of dry-etching the Al film, there may be generated residues of a titanium (expressed as Ti hereinafter)/titanium nitride (expressed as TiN hereinafter) stacked film, which is an underlying film (barrier metal film). The generation may cause, for example, a short circuit between the interconnections.

For an Al interconnection, a stacked structure is generally used which has, from the lowermost position of the structure, a barrier metal film (Ti/TiN stacked film), an Al film, and a cap metal film (Ti/TiN stacked film) in turn. It is known that the crystal orientation of the barrier metal layer affects the morphology of the Al film, which is formed on the barrier metal layer.

As a background technique in the present technical field, a technique as described in Patent Literature 1 listed below is known. Patent Literature 1 discloses a technique of orienting the crystal orientation of a Ti film and that of a TiN film, these films being configured as a barrier metal film used as an underlying film below an Al interconnection, to (002) and (111), respectively, thereby intensifying the (111) orientation of the Al film to improve the morphology of the Al film.

Patent Literature 2 also discloses that in order to make individual crystal orientations of a barrier metal consistent with each other, it is effective to perform the so-called shutter deposition before Ti is formed, or deposited into a film.

Furthermore, Patent Literature 3 discloses that in order to control the crystal orientation of a barrier metal, it is effective to form a homogeneous TiO₂ film between a Ti film and an interlayer film.

### CITATION LIST

### Patent Literatures

Patent Literature 1: JP H10-93160 A
Patent Literature 2: JP 2007-311461 A
Patent Literature 3: JP 2008-311315 A

In the case of forming a stacked film of a Ti film and a TiN film which are configured as a barrier metal film by a sputtering method, the Ti film and the TiN film are formed in the same processing chamber; thus, after the formation of the TiN film, the front surface of the Ti target has been nitrided. Accordingly, when the next wafer is processed, the front surface of the nitrided target is sputtered at an initial stage of the formation of the Ti film. Consequently, nitrogen is contained in the film of barrier metal Ti that is formed on the wafer.

As described in Patent Literature 1, when, about the barrier metal film, the crystal orientation of Ti is directed to (002) and that of TiN is directed to (111), the crystal orientation of the Al film formed thereon becomes (111), so that this film is made good in morphology. It is also known that when the crystal orientation of the Al film becomes (111), the interconnection is also improved in reliability.

However, when nitrogen is contained in the Ti film, which is the lowest film, individual crystal orientations of the Ti film are not uniformly made consistent with each other into the (002) direction. Thus, the Al interconnection is deteriorated in morphology, and the interconnection is lowered in reliability.

In order to cause nitrogen not to be contained in a film of Ti, which is a barrier metal, for example, it is advisable to form a TiN film, and subsequently remove a nitrided film on the outermost layer of the target, as disclosed in Patent Literature 2. Specifically, a wafer-simulated plate, which is called a shutter disk, is carried onto a stage to cover the stage therewith, and further sputtering with argon (expressed as Ar hereinafter) gas is applied to the workpiece. According to this method, however, it is necessary to carry the shutter onto the stage whenever a single water is processed. Thus, the productivity of semiconductor devices to be produced is remarkably deteriorated.

An object of the present invention is to improve a semiconductor device in reliability. Another object thereof is to improve a semiconductor device in productivity. Other objects and novel features will be made evident from the description of the present specification and attached drawings.

### SUMMARY OF THE INVENTION

According to an aspect of the present invention, in the formation of a Ti/TiN stacked film, about a mixed gas of Ar gas and nitrogen (hereinafter expressed as N₂) gas that is used at the time of forming a TiN film by a sputtering method, the supply of the N₂ gas is turned off (i.e., is stopped) before that of the Ar gas.

According to the aspect of the present invention, a semiconductor device is improved in reliability, and further the semiconductor device is improved in productivity.

### BRIEF DESCRIPTION OF THE DRAWINGS

FIG. 1A is a view illustrating a target of a sputtering chamber and a stacked film formed on a substrate according to a first comparatively investigating example;

FIG. 1B is a view illustrating a target of a sputtering chamber and a stacked film formed on a substrate according to a second comparatively investigating example;

FIG. 2 is a sectional view of a main region of a semiconductor device according to an example of the present invention;

FIG. 3 is a schematic view of a sputtering machine according to the example of the present invention;

FIG. 4 is a view illustrating a gas supply line and a gas exhaust line of the sputtering chamber according to the example of the present invention;

FIG. 5 is a timing chart of a partial process of a method of the example of the present invention for producing a semiconductor device;

FIG. 6 is a sectional view of a main region of a semiconductor device according to another example of the present invention; and

FIG. 7 is a graph showing a relationship between a Ti film and the defect density thereof.

### DESCRIPTION OF THE PREFERRED EMBODIMENTS

Hereinafter, with reference to the drawings, examples of the present invention will be described. The same reference sings are attached to the same structures or members, respectively, in the individual drawings. About the same structures or members, any overlapped detailed description thereon is omitted.

### Example 1

An Al interconnection of a semiconductor device is generally formed through steps as described below.

A sputtering machine is initially used to form a stacked film having, from the lowermost position thereof, a Ti film, a TiN film, an Al film, a Ti film, and a TiN film in turn. Films (underlying films) below the Al film, that is, the Ti film and the TiN film of lower layers are called a barrier metal film. Films above the Al film, that is, the Ti film and the TiN film of upper layers are called a cap metal film. The Al film may be a pure Al film. However, the Al film is usually an Al film to which a different metal material, such as copper (expressed as Cu hereinafter) or silicon (expressed as Si hereinafter), is added in a trace amount to prevent electro-migration. An Al—Cu film, in which Cu is added to Al, is most frequently used.

These metal films are each formed by a sputtering method. In order that the films of the above-mentioned stacked film structure are stacked onto each other without being exposed to the atmosphere, a multi-chamber type film-depositing machine is usually used in which a wafer can be carried in a vacuum.

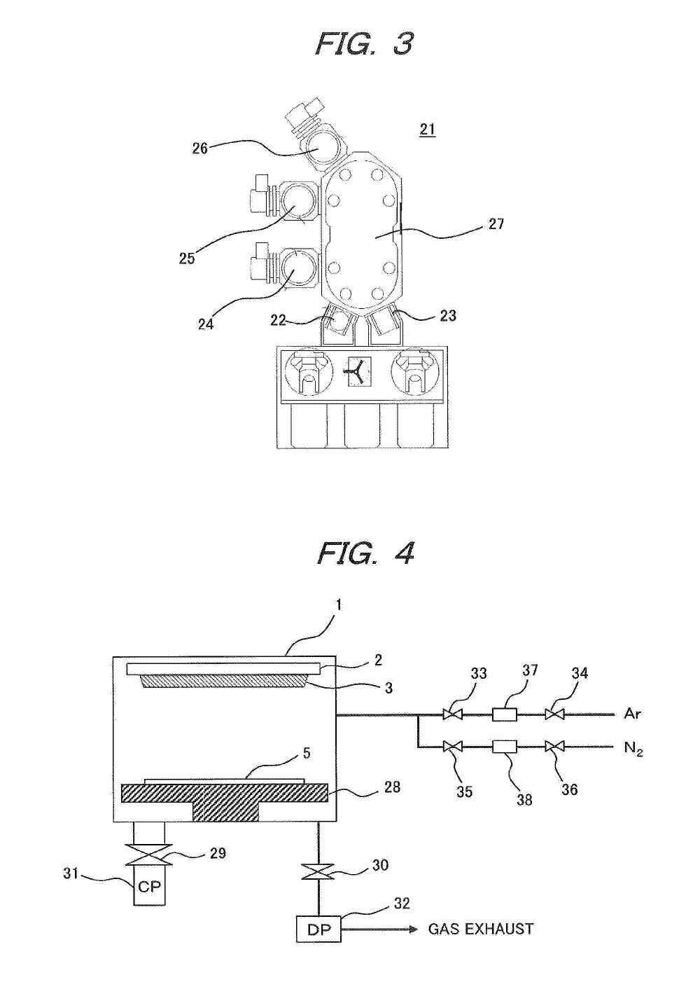

As illustrated in FIG. 3, this multi-chamber type sputtering machine has three chambers (processing chambers) connected to a vacuum carrying chamber 27.

The three chambers are composed of a barrier-metal-film-forming sputtering chamber (sputtering-chamber-A 24) for forming the Ti/TiN stacked film which is a barrier metal film, an Al-film-forming sputtering chamber (sputtering-chamber-B 25) for forming an Al film, and a cap-metal-film-forming sputtering chamber (sputtering-chamber-C 26) for forming a Ti/TiN film which is a cap metal film.

In each of the barrier-metal-film-forming chamber and the cap-metal-film-forming chamber, a Ti target is used as a raw material (target material).

In each Ti-film-forming step, Ar gas is supplied into the sputtering chamber, and a high frequency (RF) bias or a direct current (DC) bias is applied to the Ti target to make the Ar gas into plasma. By the Ar plasma, the Ti target is sputtered to form a Ti film over a wafer.

In each TiN-film-forming step, a mixed gas of Ar gas and N₂ gas is supplied into the sputtering chamber, and a high frequency (RF) bias or a direct current (DC) bias is applied to the Ti target to make the Ar/N₂ mixed gas into plasma. By the Ar/N₂ plasma, the Ti target is sputtered to form a TiN film over the wafer.

Next, a bottom-anti-reflective-layer (BARL) is formed on the useful-for-Al-interconnection metal film (stacked film), which is formed as described above.

Subsequently, a photoresist is applied onto the bottom-anti-reflective-layer, and the resultant is exposed to light into a predetermined pattern by lithography.

Lastly, the workpiece is dry-etched to remove unnecessary portions of the useful-for-Al-interconnection metal film (stacked film) to form Al interconnections.

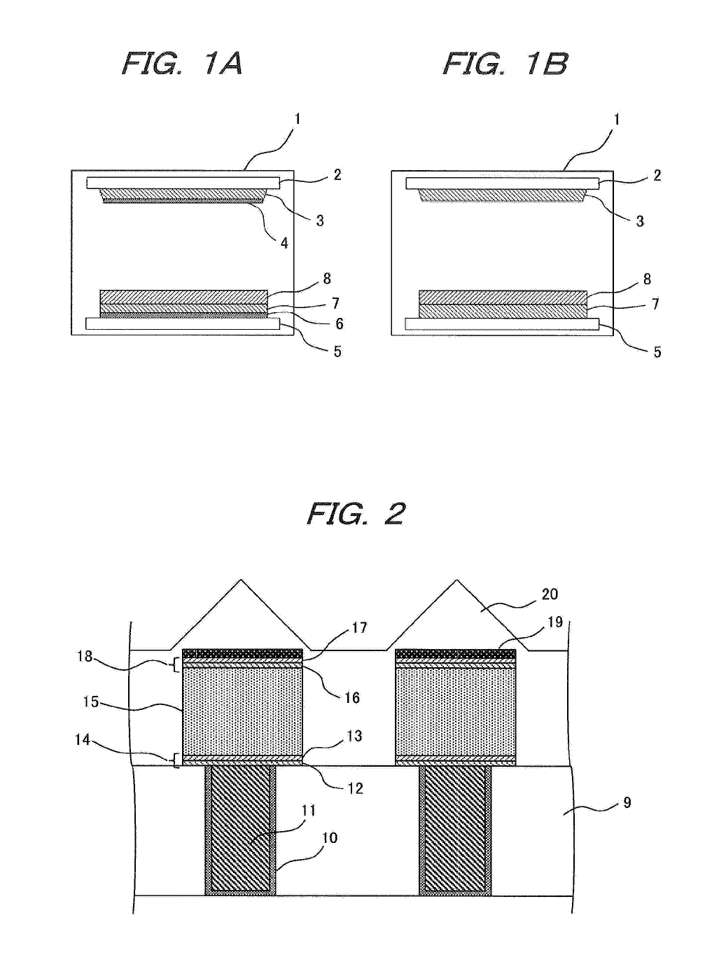

As a first comparatively investigating example, FIG. 1A illustrates a situation of a Ti target and a Ti/TiN stacked film formed on a wafer when no shutter deposition is performed. FIG. 1A is a sectional view that schematically illustrates a sputtering chamber, the Ti target and the wafer.

As described above, at the time of TiN-film-formation, N₂ gas is supplied, together with Ar gas, into the chamber; thus, a TiN layer 4 is formed on the outermost surface of the Ti target, which is a target 3. Since the TiN layer 4 has been formed on the outermost surface of the Ti target 3, the nitrided target surface is sputtered at an initial stage of Ti-film-formation when the next wafer is processed. Consequently, a Ti film 6 containing nitrogen is formed on this wafer, which is a wafer 5. As a result, individual crystal orientations of a Ti film 7 are not uniformly made consistent with each other to (002) orientation so that a TiN film 8 and an Al film (not illustrated) to be subsequently formed are not uniform in crystal orientation, either.

As a second comparatively investigating example, FIG. 1B illustrates a situation of a Ti target and a Ti/TiN stacked film formed on a wafer when shutter deposition is performed. When the shutter deposition is performed, a shutter disk is carried onto a stage and subsequently the outermost surface of a Ti target 3 is sputtered with Ar plasma. Consequently, a TiN layer as the outermost layer of the Ti target 3 is removed so that pure Ti is made naked to the resultant outermost surface of the Ti target 3.

For this reason, when the next wafer is processed, pure Ti is sputtered from an initial stage of Ti-film-formation. Thus, a Ti film containing nitrogen is not formed onto the wafer, which is a wafer 5. As a result, a Ti film 7 in which individual crystal orientations are uniformly made consistent with each other to (002) orientation can be formed on the wafer 5. Thus, individual crystal orientations of a TiN film 8 formed on this Ti film 7 can also be uniformly made consistent with each other to (111) orientation. Furthermore, individual crystal orientations of an Al film (not illustrated) formed on this TiN film 8 can also be uniformly made consistent with each other to (111) orientation. However, as described above, this method requires the step of performing the shutter deposition, so that the sputtering machine is deteriorated in producing performance.

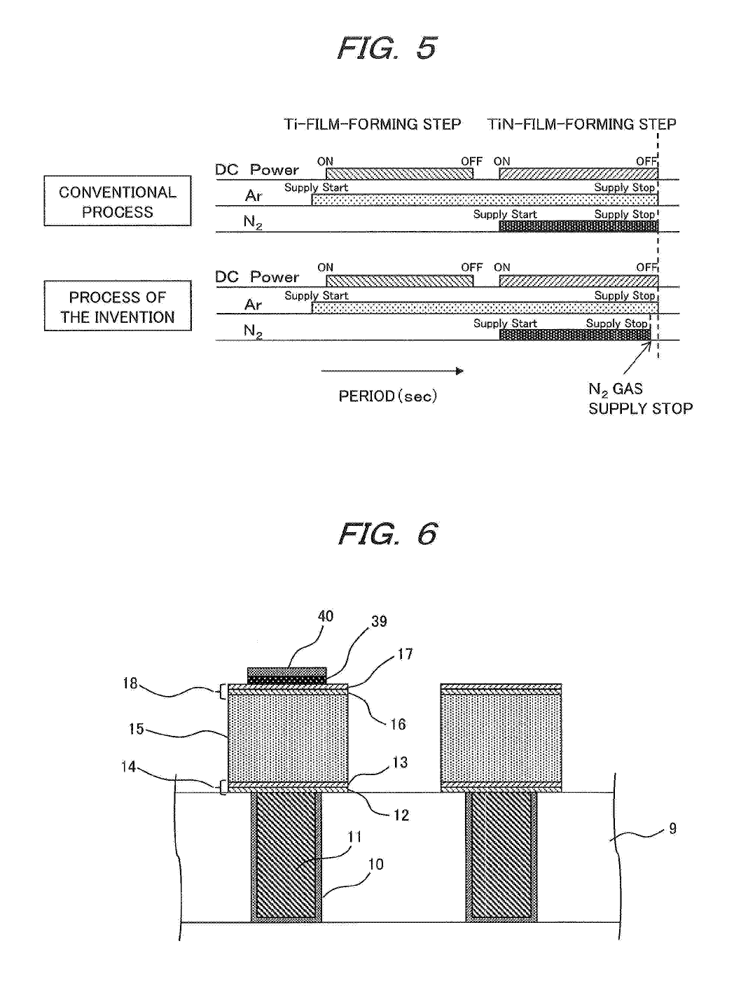

Referring to FIGS. 2 to 5, the following will describe a method for forming a Ti/TiN stacked film in the present example. FIG. 2 is a sectional view that schematically illustrates Al interconnections according to the present example, and plugs through which the Al interconnections are electrically connected to lower interconnections and/or elements. FIG. 3 illustrates a multi-chamber type sputtering machine used in the present example. FIG. 4 is a view that schematically illustrates a sputtering chamber of the sputtering machine, and gas supplying lines. FIG. 5 is a timing chart showing a processing for forming a Ti/TiN stacked film in each of a conventional process and a process of the present example.

As illustrated in FIG. 2, a semiconductor device in the present example includes a semiconductor substrate (wafer); and on the semiconductor substrate, plural semiconductor elements each made of a MOSFET are formed. Plural interconnection layers are formed on the individual semiconductor elements. In FIG. 2, the illustration of the semiconductor elements is omitted. FIG. 2 illustrates a state of an insulating film 9 after this film 9 is formed on the semiconductor elements. Contact holes are made in the insulating film 9, and plugs are buried into the contact holes, respectively. The plugs are each composed of a barrier metal film 10 and an electroconductive film 11. An Al film 15 that becomes a main body of a useful-for-Al-interconnection metal film is electrically connected, through the plugs, to the semiconductor elements on the semiconductor substrate. The barrier metal film 10 is, for example, a titanium nitride film, or a stacked film of titanium and titanium nitride. The electroconductive film 11 is made of, for example, tungsten.

A barrier metal film 14 is formed over the barrier metal film 10 and the electroconductive film 11. This barrier metal film 14 is constituted by a stacked film of a titanium film (Ti film) 12 and a titanium nitride film (TiN film) 13. About the respective film thicknesses of these films, the film thickness of the Ti film 12 is from about 10 to 30 nm, and that of the TiN film 13 is from about 15 to 50 nm.

The aluminum film (Al film) 15 is formed on the barrier metal film 14, and has a film thickness of about 150 to 390 nm. The Al film 15 is a film that becomes the main body of the useful-for-Al-interconnection metal film, and may be a film containing an additive such as Cu. In other words, the Al film 15 may be an Al—Cu film containing Al as a main component.

A cap metal film 18 is formed on the Al film 15. This cap metal film 18 is a stacked film of a titanium film (Ti film) 16 and a titanium nitride (TiN film) 17. About the respective film thicknesses of these films, the film thickness of the Ti film 16 is from about 5 to 15 nm, and that of the TiN film 17 is from about 20 to 100 nm.

A bottom-anti-reflective-layer 19 which is, for example, a silicon oxynitride film is formed on the cap metal film 18, and has a film thickness of, for example, about 20 to 50 nm. A between-interconnection insulating film 20 is formed on the bottom-anti-reflective-layer 19 to insulate the Al interconnections electrically from each other. In the present example, a case where the semiconductor device has the bottom-anti-reflective-layer 19 is demonstrated. However, this film is not necessarily required.

No nitrogen-containing layer is formed on the Ti film 12, which partially constitutes the barrier metal film 14, and thus individual crystal orientations of the Ti film 12 are uniformly made consistent with each other to (002) orientation. Moreover, individual crystal orientations of the TiN film 13 on the Ti film 12 are uniformly made consistent with each other to (111) orientation, and further individual crystal orientations of the Al film 15 formed thereon are also uniformly made consistent with each other to (111) orientation.

In the present example, the useful-for-Al-interconnection metal film (stacked film) is formed, using a sputtering machine as illustrated in FIG. 3, which is in such a multi-chamber form that a semiconductor wafer can be carried in a vacuum. The wafer is processed under sputtering conditions shown in Table 1.

TABLE 1

| | Steps | | | | | | | |
|---|---|---|---|---|---|---|---|---|
| | 1 | 2 | 3 | 4 | 5 | 6 | 7 | 8 |
| Parameters | GAS | RAMP | TI DEPO | GAS | RAMP | TIN DEPO | N₂ OFF | PUMP |
| Step Period (sec) | 15.0 | 3.0 | 5.0 to | 15.0 | 3.0 | 5.0 to | 0.5 to | 5.0 |
| | | | 15.0 | | | 30.0 | 3.0 | |
| DC Power (W) | 0 | 1000 | 2000 to | 0 | 1000 | 2000 to | 2000 to | 0 |
| | | | 4000 | | | 15000 | 15000 | |
| Ar Flow Rate (sccm) | 20 to | 20 to | 20 to | 20 to | 20 to | 20 to | 20 to | — |
| | 50 | 50 | 50 | 50 | 50 | 50 | 50 | |
| N₂ Flow Rate (sccm) | — | — | — | 70 to | 70 to | 70 to | 0 | — |
| | | | | 100 | 100 | 100 | | |

Initially, through a loader 22 of the sputtering machine, which is a machine 21, a wafer is carried into a vacuum carrying chamber 27. Next, through a wafer carrying mechanism (not illustrated) inside the vacuum carrying chamber 27, the wafer is carried into the sputtering-chamber-A 24, and the wafer (represented by reference number 5 in FIG. 4) is put onto a stage (represented by reference number 28 in FIG. 4) inside the sputtering-chamber-A 24.

Subsequently, the sputtering-chamber-A 24 is vacuum-evacuated, and then a sputtering processing shown in Table 1 is started.

In the sputtering processing shown in Table 1, Ar gas is first introduced into the sputtering-chamber-A 24 (step 1 in Table 1).

Next, the application of a direct current (DC) bias to a Ti target is started. In order to prevent a local arc discharge and a breakdown that are caused by an abrupt application of a high electric power, a relatively low electric power (of about 1000 W in this case) is applied for about 3.0 seconds (step 2 in Table 1).

Subsequently, the processing is shifted to a Ti-film-forming step (step 3 in Table 1) to form a Ti film.

Thereafter, the application of the direct current (DC) bias is once stopped, and then while the Ar gas is supplied, the supply of N₂ gas is started. The flow rate of the supplied Ar/N₂ mixed gas into the sputtering-chamber-A 24 is then made stable (step 4 in Table 1).

Subsequently, in the same way as in step 2, in order to avoid an abrupt application of a high electric power, a relatively low electric power (of about 1000 W in this case) is applied for about 3.0 seconds (step 5 in Table 1).

Subsequently, the processing is shifted to a TiN-film-forming step to form a TiN film (step 6 in Table 1).

Furthermore, the processing is shifted to step 7 in Table 1 to stop the supply the N₂ gas while the supply of the Ar gas and the application of the direct current (DC) bias are continued (step 7 in Table 1).

Lastly, the supply of the Ar gas and the application of the direct current (DC) bias are stopped, and the sputtering-chamber-A 24 is vacuum-evacuated to end the processing (step 8 in Table 1).

The supply of the Ar gas and that of the N₂ gas are attained, using gas supply lines as illustrated in FIG. 4. An Ar gas supply line of these lines is composed to have, at the downstream side thereof, a gas supply valve 33, an MFC (mass-flow-controller) 37, and a gas supply valve 34. A N₂ gas supply line of the lines is composed to have, at the downstream side thereof, a gas supply valve 35, an MFC (mass-flow-controller) 38, and a gas supply valve 36.

Furthermore, a gas exhaust line of the lines is equipped with a gate valve 29, a rough line valve 30, a cryopump 31, and a dry pump 32.

Referring to FIG. 5, the following will describe a flow of the above-mentioned formation of the Ti/TiN stacked film in the present example as compared with a conventional process flow.

As shown in FIG. 5, according to the conventional process, the supply of Ar gas into a sputtering chamber is initially started. When the flow rate thereof is then stabilized, a direct current (DC) bias is applied to start the formation of a Ti film. After a period necessary for the formation of the Ti film into a desired film thickness elapses, the application of the direct current (DC) bias is stopped to end the formation of the Ti film.

Thereafter, the supply of the N₂ gas is started, and a direct current (DC) bias is applied to start the formation of a TiN film. After a period necessary for the formation of the TiN film into a desired film thickness elapses, the application of the direct current (DC) bias is stopped at the same time when the supply of the Ar gas and that of the N₂ are stopped. Thus, the formation of the TiN film is ended.

In the meantime, in the process flow of the present example, its Ti-film-forming step is the same as in the conventional process. However, in its TiN-film-forming step, the supply of N₂ gas is stopped before the supply of Ar gas is stopped and the application of a direct current (DC) bias is stopped. A difference in time (N₂-off period) between the supply stop of the N₂ gas and the respective supply stops of the Ar gas and the application of the direct current (DC) bias is set into the range of, for example, about 0.5 to 3.0 second, as shown in step 7 in Table 1.

However, conditions for removing a TiN layer formed on the outermost layer of the Ti target are determined in accordance with a balance between the direct current (DC) bias (DC power) and the N₂-off period. Thus, the N₂-off period is not limited into the range of 0.5 to 3.0 seconds, and may be set to an appropriate period while the state of the Ti film (the degree of the nitrogen content in the film) formed on the front surface of the wafer is monitored by a method of measuring the resistance value of the Ti film, or some other method.

By a method as described above, the barrier metal film 14 is formed, and subsequently the wafer is carried into the sputtering-chamber-B 25 in FIG. 3. The Al film 15 is then formed by sputtering using an Al target and Ar gas plasma.

Subsequently, the wafer is carried into the sputtering-chamber-C 26 in FIG. 3, and then the cap metal film 18, which is the stacked film of the Ti film 16 and the TiN film 17, is formed. For this process for forming the cap metal film 18, the conventional process shown in FIG. 5 may be used, or the process of the present example may be used. It is however preferred to use the process of the present invention, which is illustrated in FIG. 5, in order to keep the surface of the target inside the sputtering-chamber-C 26 in a clean state to form the Ti film 16 as a film higher in reliability.

Thereafter, the bottom-anti-reflective-layer 19 is formed onto the cap metal film 18 by, for example, a CVD method. As described above, the bottom-anti-reflective-layer 19 may be a silicon oxynitride film. In the present example, a case where the bottom-anti-reflective-layer 19 is used is demonstrated. However, this bottom-anti-reflective-layer 19 is not necessarily required. Thus, when an appropriate light exposure is conducted, the bottom-anti-reflective-layer 19 may be omitted.

Subsequently, a resist film is applied onto the bottom-anti-reflective-layer 19, and then the resultant workpiece is exposed to light into a predetermined pattern. Thereafter, the workpiece is subjected to dry-etching treatment to work each of the TiN film 17, the Ti film 16, the Al film 15, the TiN film 13 and the Ti film 12. In this way, interconnections are formed.

As described above, in the step of forming the TiN film, the supply of the N₂ gas is turned off (the stop of the supply) before that of the Ar gas is turned off, thereby lowering the N₂ partial pressure in the sputtering chamber. In this way, N₂ ions and N₂ radicals in the sputtering chamber are each lowered in quantity, so that the nitriding of the surface of the target is restrained. Moreover, the nitride layer of the outermost layer of the target is removed by the Ar sputtering.

Accordingly, when a Ti film is formed onto a surface (main surface) of a wafer to be next carried, the target surface is realizing a clean state so that no nitrogen is incorporated into the Ti film.

As described above, according to the method of the present example for forming the Ti/TiN stacked film, individual crystal orientations of the Ti film, which partially constitutes the useful-for-Al-interconnection barrier metal film, can be uniformly made consistent with each other to (002). As a result, individual crystal orientations of the TiN film formed thereon can be uniformly made consistent with each other to (111). Individual crystal orientations of the Al film further formed thereon can also be uniformly made consistent with each other to (111). In this way, the Al film is improved in morphology (surface smoothness). In other words, the semiconductor device according to the present invention example can be improved in reliability.

Differently from the second comparatively investigating example described with reference to FIG. 1B, the present example does not require shutter-depositing steps that should be performed one by one, and makes it possible to heighten the cleanness of the targets only by adjusting the gas supplies. In other words, the semiconductor device according to the present example can be improved in productivity.

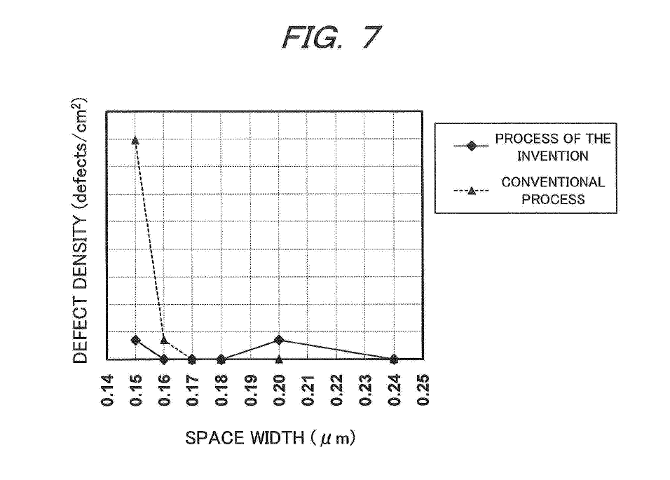

FIG. 7 is a graph showing a relationship between the defect density of the Ti film and the space width between the interconnections in each of the present example and the first comparatively investigating example. A conventional process in FIG. 7 corresponds to the first comparatively investigating example. When the space width between the Al interconnections is large, a large difference is not observed between the two examples. When the space width becomes smaller, the defect density of the Ti film becomes larger. This would be because when the Ti film of the barrier metal contains a nitrogen component, residues of the barrier metal are easily generated when the workpiece is subjected to dry-etching as described above, so that the residues may cause a short circuit between the interconnections.

The use of the present example makes it possible to prevent a short circuit between such interconnections. Specifically, the example is particularly useful for a case where a space between interconnections of a semiconductor device is made narrow to have a space width of less than 0.16 μm by making the semiconductor device fine. Thus, a short circuit between the interconnections can be prevented.

Accordingly, the use of the method of the present example for forming a Ti/TiN stacked film makes it possible to improve an Al film of the example in morphology to improve Al interconnections thereof in reliability and improve the production yield of such stacked films.

### Example 2

Referring to FIG. 6, the following will describe a semiconductor device according to the present example. The semiconductor device according to the example is different from the semiconductor device illustrated in FIG. 2 in that in the former, a high dielectric film 39 and a metal film 40 are formed over a TiN film 17 which partially constitutes a cap metal 18. This metal film 40 functions as an upper electrode of a capacitive element. In other words, the TiN film 17, the high dielectric film 39 and the metal film 40 are configured as a capacitive element (MIM element).

The semiconductor device illustrated in FIG. 6 is formed by, for example, a production method as described hereinafter. Useful-for-Al-interconnection metal films up to the cap metal film 18 are formed by the method described in Example 1, and then the high dielectric film 39 is formed onto the TiN film 17 by a CVD method. Subsequently, the metal film 40 is formed onto the high dielectric film 39 by a sputtering method. Subsequently, a photoresist film is applied to the workpiece, and the resultant is exposed to light into a predetermined pattern. The metal film 40 and the high dielectric film 39 are then dry-etched to form the above-mentioned capacitive element, in which the TiN film 17 is a lower electrode, and the metal film 40 is an upper electrode. Subsequently, a photoresist film having a predetermined pattern form is formed on the useful-for-Al-interconnection metal films. Thereafter, the photoresist film is used as a mask to subject the workpiece to dry-etching to work each of the TiN film 17, the Ti film 16, the Al film 15, the TiN film 13 and the Ti film 12.

For the semiconductor device of the present example, as shown in Table 1 and FIG. 5, in the same way as in Example 1, the supply of N₂ gas is turned off (i.e., is stopped) before that of Ar gas in the step of forming the TiN film 13. In this way, in the same manner as in Example 1, the Al film 15 is improved in morphology (surface smoothness), so that an improvement is also made in the morphology (surface smoothness) of the Ti film 16 and the TiN film 17 formed over the Al film 15. As a result, an improvement is also made in the morphology (surface smoothness) of the high dielectric film 39 and the metal film 40, which are further formed over the TiN film 17. The capacitive element (MIM) can be formed to have a higher reliability.

Also in the formation of the TiN film 17, which partially constitutes the cap metal 18, the TiN film 17 may be formed by the method shown in Table 1 and FIG. 5. In other words, in the TiN-film-forming step, the supply of N₂ is turned off (i.e., is stopped) before that of Ar gas.

The above has described the invention made by the inventors specifically on the basis of the examples thereof. However, the invention is not limited to the examples. Thus, of course, the examples may each be variously changed as far as the changed example does not depart from the subject matter of the invention. When at least one of the plural interconnection layers is, for example, an Al interconnection layer, the method of Example 1 is usable for the Al interconnection. When the plural interconnection layers are Cu interconnections formed through the damascene process, the method of Example 1 is usable for an Al interconnection functioning as a pad electrode of the topmost layer. A semiconductor device including such plural interconnection layers is not limited to an SOC, a microcomputer, a flash memory, or any other device similar thereto. Thus, the semiconductor device may be an optical element such as a CMOS image sensor or a photodiode.

### REFERENCE NUMBER LIST

1: sputtering chamber, 2: backing plate, 3: Ti target, 4: TiN layer, 5: semiconductor substrate (wafer), 6: Ti film containing nitrogen, 7, 12 and 16: Ti films, 8, 13 and 17: TiN films, 9: insulating film, 10: barrier metal, 11: electroconductive film, 14: barrier metal film, 15: Al film, 18: cap metal film, 19: bottom-anti-reflective-layer, 20: between-interconnection insulating film, 21: sputtering machine, 22: loader, 23: unloader, 24: sputtering-chamber-A, 25: sputtering-chamber-B, 26: sputtering-chamber-C, 27: vacuum carrying chamber, 28: stage, 29: gate valve, 30: rough line valve, 31: cryopump, 32: dry pump, 33, 34, 35 and 36: gas supply valves, 37 and 38: MFCs, 39: high dielectric film, and 40: metal film.

What is claimed is:

1. A method for forming a Ti/TiN stacked film, comprising the steps of:
forming a first Ti film over a first substrate by a sputtering method, and
forming a first TiN film over the first Ti film by a sputtering method,
wherein in the step of forming the first TiN film, the used sputtering method is a sputtering method using a Ti target and an Ar/N₂ mixed gas, and the supply of N₂ gas is stopped before the supply of Ar gas.

2. The Ti/TiN stacked film forming method according to claim 1, further comprising the steps of:
forming an Al film over the first TiN film by a sputtering method,
forming a second Ti film different from the first Ti film over the Al film by a sputtering method, and
forming a second TiN film different from the first TiN film over the second Ti film by a sputtering method,
wherein a stacked film comprising the first Ti film, the first TiN film, the Al film, the second Ti film, and the second TiN film is patterned by photolithography and dry-etching, thereby forming an Al interconnection.

3. The Ti/TiN stacked film forming method according to claim 2,
wherein in the step of forming the second TiN film, the used sputtering method is a sputtering method using a Ti target and an Ar/N₂ mixed gas, and the supply of N₂ gas is stopped before the supply of Ar gas.

4. The Ti/TiN stacked film forming method according to claim 3, further comprising the steps:
forming a high dielectric film over the second TiN film, and
forming a metal film over the high dielectric film, wherein a stacked film comprising the high dielectric film and the metal film is patterned by photolithography and dry-etching, thereby forming a capacitive element.

5. The Ti/TiN stacked film forming method according to claim 2, which is performed inside a sputtering machine having a first processing chamber, a second processing chamber, and a third processing chamber,
wherein the first Ti film and the first TiN film are formed in the first processing chamber,
the Al film is formed in the second processing chamber, which is different from the first processing chamber,
the second Ti film and the second TiN film are formed in the third processing chamber, which is different from the first and second processing chambers,
after the first TiN film is formed in the first processing chamber, the first substrate is carried out from the first processing chamber,
a second substrate different from the first substrate is carried into the first processing chamber,
a third Ti film is formed over the second substrate,
the formation of the third TiN film is attained, using a sputtering method using a Ti target and an Ar/N₂ mixed gas, and the supply of N₂ gas is stopped before the supply of Ar gas.

6. The Ti/TiN stacked film forming method according to claim 5,
wherein by stopping the supply of the N₂ gas before the supply of the Ar gas at the time of forming the first TiN film, a nitride on a surface of the Ti target in the first processing chamber has been removed by Ar plasma at the time of forming the third Ti film over the second substrate.

7. The Ti/TiN stacked film forming method according to claim 1, which is performed in a sputtering machine having a first processing chamber,
wherein after the first TiN film is formed, the first substrate is carried out from the first processing chamber,
a second substrate different from the first substrate is carried into the first processing chamber,
a second Ti film is formed over the second substrate,
a second TiN film is formed over the second Ti film, and
at the time of forming the second TiN film, the supply of N₂ gas is stopped before the supply of Ar gas.

8. A method for producing a semiconductor device, the method being performed using a sputtering machine comprising a first processing chamber and a first stage inside the first processing chamber, and
the method comprising the steps:
(a) carrying a first substrate into the first processing chamber, and putting the first substrate over the first stage,
(b) vacuum-evacuating the first processing chamber after the step (a),
(c) supplying Ar gas into the first processing chamber after the step (b),
(d) applying a voltage to a first metal target arranged oppositely to the first stage after the step (b),
(e) supplying N₂ gas into the first processing chamber after the step (b),
(f) stopping the supply of the N₂ gas after the steps (c) to (e), and
(g) stopping the supply of the Ar gas and the application of the voltage after the step (f).

9. The semiconductor device producing method according to claim 8,
wherein before the step (e), the application of the voltage is once stopped, and
in the step (e), the supply of the N₂ gas is started, and subsequently a voltage is again applied to the metal target.

10. The semiconductor device producing method according to claim 8,
wherein the first metal target is a Ti target comprising Ti as a main component.

11. The semiconductor device producing method according to claim 10,
the sputtering machine further comprising a second processing chamber and a second stage inside the second processing chamber; and
the method further comprising, after the step (g), the steps of:
(h) carrying out the first substrate from the first processing chamber,
(i) carrying the first substrate into the second processing chamber and putting the first substrate over the second stage after the step (h),
(j) vacuum-evacuating the second processing chamber after the step (i),
(k) supplying Ar gas into the second processing chamber after the step (j), and
(l) applying a voltage to an Al target arranged oppositely to the second stage after the step (j).

12. The semiconductor device producing method according to claim 11,
the sputtering machine further comprising a third processing chamber and a third stage inside the third processing chamber;
the method further comprising, after the step (l), the steps of:
(m) carrying out the first substrate from the second processing chamber,
(n) carrying the first substrate into the third processing chamber and putting the first substrate over the third stage after the step (m),
(o) vacuum-evacuating the third processing chamber after the step (n),
(p) supplying Ar gas into the third processing chamber after the step (o),
(q) applying a voltage to a second metal target arranged oppositely to the third stage after the step (o),
(r) supplying N₂ gas into the third processing chamber after the step (o),
(s) stopping the supply of the N₂ gas after the steps (p) to (r), and
(t) stopping the supply of the Ar gas and the application of the voltage after the step (s).

13. The semiconductor device producing method according to claim 12,
wherein the second metal target is a Ti target comprising Ti as a main component.

14. The semiconductor device producing method according to claim 8, further comprising, after the step (g), the steps of:
(u) carrying out the first substrate from the first processing chamber,
(v) carrying the second substrate into the first processing chamber and putting the second substrate over the first stage after the step (u),
(w) vacuum-evacuating the first processing chamber after the step (v),
(x) supplying Ar gas into the first processing chamber after the step (w),
(y) applying a voltage to between the first stage and the first metal target arranged oppositely to the first stage after the step (w),
(z) supplying N₂ gas into the first processing chamber after the step (w),
(a′) stopping the supply of the N₂ gas after the steps (x) to (z), and
(b′) stopping the supply of the Ar gas and the application of the voltage after the step (a′).

15. The semiconductor device producing method according to claim 14,
wherein the first metal target is a Ti target comprising Ti as a main component.
